(19) United States
(12) Patent Application Publication
(10) Pub. No.: US 2004/0065546 A1
(43) Pub. Date: Apr. 8, 2004

(54) Method to recover spent components of a sputter target

(76) Inventors: Christopher A. Michaluk, Gilbertsville, PA (US); Robert B. Ford, Washington Court House, OH (US)

Correspondence Address: Martha Ann Finnegan, Esq., Cabot Corporation, 157 Concord Road, Billerica, MA, 01821-7001, US

(21) Appl. No.: 10/674,570

(22) Filed: Sep. 30, 2003

Related U.S. Application Data
(60) Provisional application No. 60/416,048, filed on Oct. 4, 2002.

(51) Int. Cl. C23C 14/34; C25B 13/00

(52) U.S. Cl. 204/298.12; 148/240

(57) ABSTRACT

A method to recover components of a sputter target assembly having a target bonded onto a backing plate is described. The method includes hydriding the tantalum or niobium target to a tantalum hydride or niobium hydride, respectively and then separating the tantalum hydride or niobium hydride from the backing plate. Sputter targets are further described as well as subsequent process steps.

This application claims the benefit under 35 U.S.C. §119(e) of prior U.S. Provisional Patent Application No. 60/416,048 filed Oct. 4, 2002, which is incorporated in its entirety by reference herein.

### BACKGROUND OF THE INVENTION

The present invention relates to sputter targets. More particularly, the present invention relates to spent sputter targets and the recovery of the components of the spent target for subsequent use.

Typically, a sputtering target, such as a tantalum sputtering target assembly contains a tantalum target blank which is bonded to a machined backing plate which typically is made of copper or aluminum. For assemblies that utilize a low melting point solder as the bonding agent to bond the backing plate onto the target blank, the spent target blank and machined backing plate can then subsequently be easily reclaimed by heating the assembly to a temperature above the melting point of the solder and then separating the two components. The bonding of the target blanks to a backing plate using such low melting point solders is not as popular and such bonding methods are not as reliable as metallurgically attached bonding methods. However, when metallurgically attached bonding methods are used such as, diffusion bonding, explosion bonding, electron beam welding, inertia welding, and the like, the only way currently known to separate the spent target blank from the backing plate is by a destructive manner, such as machining or chemically etching.

Accordingly, methods to recover the spent components of the sputter target assembly would be valuable from an economic point of view as well as a environmental point of view.

### SUMMARY OF THE PRESENT INVENTION

A feature of the present invention is to provide a method to recover spent components of a sputter target assembly.

Another feature of the present invention is to provide a means to avoid separating the backing plate from the spent target blank in a destructive manner.

A further feature of the present invention is to recover the spent components of a sputter target in order to reuse components for future sputter use or other applications.

Additional features and advantages of the present invention will be set forth in part in the description that follows, and in part will be apparent from the description, or may be learned by practice of the present invention. The objectives and other advantages of the present invention will be realized and attained by means of the elements and combinations particularly pointed out in the description and appended claims.

To achieve these and other advantages, and in accordance with the purposes of the present invention, as embodied and broadly described herein, the present invention relates to a method to recover components (e.g., spent, new, rejected) of a sputter target assembly. The sputter target assembly preferably has a tantalum or niobium target blank bonded onto a backing plate. In this method, the tantalum or niobium target is hydrided to form tantalum hydride or niobium hydride, respectively, and then the tantalum hydride or niobium hydride is separated from the backing plate.

The method can further include converting the tantalum hydride or niobium hydride to tantalum or niobium for subsequent processing, such as into other tantalum products or sputter targets. Furthermore, the backing plate, which is not destroyed, can be reused by bonding a new target onto the backing plate.

The present invention further relates a spent sputter target assembly comprising tantalum hydride or niobium hydride bonded onto a backing plate.

It is to be understood that both the foregoing general description and the following detailed description are exemplary and explanatory only and are intended to provide a further explanation of the present invention, as claimed.

### DETAILED DESCRIPTION OF THE PRESENT INVENTION

The present invention relates to sputter target assemblies. In particular, the sputter target assembly preferably has a tantalum or niobium target bonded onto a backing plate. Some of those skilled in the art refer to the target that is bonded onto the backing plate as the target blank. Preferably, the target blank is a tantalum or niobium target blank. Alloys of niobium and tantalum can also be used herein, and preferably alloys that contain a majority of niobium, tantalum, or both. The backing plate can be any conventional backing plate material used in the industry, such as copper, aluminum, titanium, any alloy thereof, and the like. For purposes of the present invention, the composition of the backing plate is not important and is typically, though not necessarily, a different material from the target blank material. For purposes of the present invention, the purity, texture, and/or grain size of the target blank can be any texture, purity, and/or grain size usable in the sputter industry or even different from current industry standards. For instance, the target blank can be 99.95% pure or higher. Exarmples of such target material can be found, for instance, in U.S. Pat. No. 6,348,113, incorporated in its entirety by reference herein. Furthermore, the sputter target assembly can contain an interlayer material that acts as a bonding aid between the target blank and the backing plate. The interlayer material can be in the form of a thin film coating applied by electroplating, electroless plating, vapor deposition, ion beam deposition, or other suitable means for depositing a thin film The interlayer can also be in the form of a foil, plate, or block. Examples of interlayer materials can include, but are not limited to zirconium and the like and are conventional in the industry, titanium as found in U.S. Pat. No. 5,863,398 and U.S. Pat. No. 6,071,389; copper, aluminum, silver, nickel, and alloys thereof, as found in U.S. Pat. No. 5,693,203, and graphite as found in U.S. Pat. No. 6,183,613 B1, each of which is incorporated in its entirety by reference herein.

As stated above, the present invention particularly relates to a method to recover spent (e.g., eroded) components of a sputter target assembly preferably having a tantalum or niobium target bonded onto a backing plate. The bonding of the target material onto the backing plate is typically a metallurgical bond, such as bonding achieved by diffusion bonding, explosion bonding, electron beam welding, inertia welding, friction brazing, and the like. For purposes of the present invention, the backing plate can be bonded onto the sputter target in any fashion even by soldering techniques though the present invention is most useful when the backing plate is bonded onto the target by metallurgical means wherein there is an interaction of the surface of the backing plate with the surface of the target material, or between the surfaces of the backing plate, interlayer material, and target material, on an atomic scale to form a metallurgical bond. The present invention is also applicable to sputtering target assemblies whereby the backing plate is bonded to the target blank by mechanical means, such as described in U.S. Pat. No. 5,230,459 and U.S. Pat. No. 5,836,506, each of which is incorporated in its entirety by reference herein.

The present invention is quite useful in the recovery of spent or rejected components of a sputter target assembly. The present invention can also be used with unused target materials. In the method, the tantalum or niobium target is hydrided to form tantalum hydride or niobium hydride. Then, the tantalum hydride or niobium hydride is separated from the backing plate. Then, as an option, the tantalum hydride or niobium hydride can be converted back to tantalum or niobium and subsequently processed as any tantalum or niobium material, such as powder.

In more detail, the tantalum or niobium target which is bonded onto a backing plate is hydrided to tantalum hydride or niobium hydride, respectively, while the tantalum or niobium target is bonded onto the backing plate. This hydriding of the tantalum or niobium to tantalum hydride or niobium hydride respectively permits the easy removal of the tantalum hydride or niobium hydride from the bonded target. The hydriding of the tantalum or niobium that forms the target or target blank can be achieved by any hydriding technique. A hydriding atmosphere and/or hydriding material (gas, liquid, and/or solid) can be used. For instance, the hydriding can be achieved by heating the tantalum or niobium target bonded to the backing plate under a positive pressure of hydrogen and heating for a predetermined time and temperature to convert the tantalum to tantalum hydride or to convert the niobium to niobium hydride without significantly distorting the machined backing plate. Typically, the times and temperatures and amounts of hydrogen to achieve this effect is dependent upon the size and shape of the tantalum or niobium target. For instance, and just an example, a planar tantalum blank approximately 12 inches in diameter a 0.250 inches thick that is diffusion bonded to a copper backing plate is placed in a retort furnace. The retort is evacuated, backfilled with argon to perform leak tests, evacuated, then backfilled with hydrogen gas. A hydrogen pressure of 3-6 atmospheres is maintained while the temperature is raised to 850° C. and held for 30 minutes to completely hydrogenate the tantalum. The hydrogen is then purged from the furnace, which is then backfilled with argon and allowed to cool to ambient temperature. Aside from hydrogen, other gases such as methane or ammonia can by used to hydride the tantalum.

For sputtering target assemblies with a backing plate comprised of material that does not hydride, such as aluminum or copper, the very friable tantalum hydride or niobium hydride is then separated from the backing plate by any separation technique, such as mechanical techniques. For instance, the tantalum hydride or niobium hydride can be removed from the backing plate by scraping, grinding, grit blasting, hammering, or chiseling and the like. Any of these techniques can be used to remove the tantalum hydride or niobium hydride from the backing plate without distorting or damaging the backing plate. Conventional tools such as air hammers and scrapers can by used to remove the tantalum or niobium hydride from the backing plate. Care should be taken in the selection of the tools so that their use will not contaminate the tantalum or niobium hydride with impurities that can not be removed by subsequent thermal, chemical, of vacuum melting processes.

At this point, the backing plate can be recovered and preferably cleaned and/or polished for subsequent use as a backing plate with new target blanks. The cleaning and polishing of the backing plate are conventional and can be applied to this recovered backing plate.

For sputtering target assembles with a backing plate comprised of a material that hydrides, such as titanium, both the tantalum or niobium target blank and backing plate are converted to their native metal hydride. here, the friable tantalum or niobium hydride is partitioned from the friable hydrided backing plate by physical means such as gravity separation, flotation, air classification, or electrostatic separation. To facilitate the separation process, the hydrided materials can first be converted into a fine powder using standard crushing, grinding, or milling techniques.

Furthermore, the tantalum hydride or niobium hydride, which has been removed from the backing plate material can then be converted to tantalum or niobium. Any manner in which to convert the hydride version of tantalum or niobium to its tantalum or niobium metal state can be used. For instance, the tantalum hydride or niobium hydride can be heated in a vacuum to a sufficient temperature to convert the tantalum hydride or niobium hydride to tantalum or niobium respectively. As an option, the tantalum hydride or niobium hydride can be first reduced to a powder form by standard or conventional milling techniques or other techniques to reduce chunks or agglomerates of metal to powder form. Once the tantalum hydride or niobium hydride is converted to tantalum or niobium, the tantalum or niobium can then be processed in a conventional manner for subsequent use. For instance, the tantalum or niobium can be melted and formed into an ingot. Alternatively, the tantalum or niobium can be used for other applications, such as in the formation of capacitor anodes, or be pressed and sintered into wire and sheet bars for subsequent processing into wire and sheet products, or otherwise be consolidated either as elemental powders or with the addition of alloy additives into sputtering target blanks or monolithic sputtering targets, X-ray targets, furnace trays and hardware, laboratory crucibles, and other unwrought or wrought product forms. Thus, the present invention forms a tantalum hydride or niobium hydride target blank which is bonded onto a backing plate and thus creates an easy mode of separating the backing plate from the target without damaging the backing plate.

Other embodiments of the present invention will be apparent to those skilled in the art from consideration of the present specification and practice of the present invention disclosed herein. It is intended that the present specification and examples be considered as exemplary only with a true scope and spirit of the invention being indicated by the following claims and equivalents thereof.

What is claimed is:

1. A method to recover components of a sputter target assembly comprising a tantalum or niobium target bonded to a backing plate, wherein said method comprising
hydriding said tantalum or niobium target to form tantalum hydride or niobium hydride, respectively; and
separating said tantalum hydride or niobium hydride from said backing plate.

2. The method of claim 1, wherein said tantalum or niobium target is an eroded tantalum or niobium target.

3. The method of claim 1, wherein said tantalum or niobium target is a tantalum alloy or niobium alloy target.

4. The method of claim 1, wherein said tantalum or niobium target is an uneroded tantalum or niobium target.

5. The method of claim 1, further comprising converting said tantalum hydride or niobium hydride to tantalum or niobium, respectively, after said separating.

6. The method of claim 1, further comprising first reducing said tantalum hydride or niobium hydride to a powder and then converting said tantalum hydride or niobium hydride powder to a tantalum or niobium powder, respectively.

7. The method of claim 1, further comprising recovering said backing plate separated from said tantalum hydride or niobium hydride.

8. The method of claim 7, wherein said backing plate is cleaned, polished, or both.

9. The method of claim 5, wherein said converting comprises heating said tantalum hydride or niobium hydride under vacuum at a sufficient temperature and time to convert said tantalum hydride or niobium hydride to tantalum or niobium, respectively.

10. The method of claim 9, wherein said heating is at a temperature of from about 800° C. to about 1000° C.

11. The method of claim 9, wherein said heating occurs at a temperature of about 850° C.

12. The method of claim 1, wherein said separating is achieved by mechanical means.

13. The method of claim 1, wherein said separating is achieved by scraping, grinding, grit blasting, or combinations thereof.

14. The method of claim 5, wherein said tantalum or niobium is melted into an ingot.

15. A sputter target comprising tantalum hydride or niobium hydride located onto a backing plate.

16. The sputter target of claim 15, wherein said sputter target is an eroded sputter target.

17. The sputter target of claim 15, wherein said backing plate comprises copper, aluminum, or alloys thereof.

18. The method of claim 1, wherein said backing plate comprises copper, aluminum, or alloys thereof.

19. The method of claim 1, wherein said tantalum or niobium target is bonded to a backing plate by diffusion bonding, explosion bonding, electron beam welding, inertia welding, or combinations thereof.

20. The sputter target of claim 15, wherein said backing plate is bonded onto said tantalum hydride or niobium hydride by diffusion bonding, explosion bonding, electron beam welding, inertia welding, or combinations thereof.

21. The sputter target of claim 15, wherein said backing plate is bonded onto said tantalum hydride by mechanical means.

22. The sputter target of claim 15, further comprising an interlayer located between said tantalum hydride or niobium hydride and said backing plate.

23. The method of claim 1, wherein said backing plate comprises a hydridable material which is hydrided during said hydriding.

24. The method of claim 23, wherein said separating comprises gravity separation, flotation, air classification, electrostatic separation, or combinations thereof.

25. The method of claim 23, wherein said hydrided backing plate is reduced to powder form.

26. The sputter target of claim 15, wherein said backing plate comprises a hydridable material.

27. The sputter target of claim 15, wherein said backing plate is hydrided.
